(19) United States
(12) Patent Application Publication
(10) Pub. No.: US 2026/0052839 A1
(43) Pub. Date: Feb. 19, 2026

(54) ELECTRONIC DEVICE

(71) Applicant: InnoLux Corporation, Miao-Li County (TW)

(72) Inventors: Chandra LIUS, Miao-Li County (TW); Kuan-Feng LEE, Miao-Li County (TW)

(21) Appl. No.: 19/269,213

(22) Filed: Jul. 15, 2025

(30) Foreign Application Priority Data
Aug. 13, 2024 (CN) 202411106445.8

(51) Int. Cl. H10K 59/121; H10K 59/12; H10K 59/65; H10K 102/00

(52) U.S. Cl. CPC H10K 59/1213; H10K 59/1201; H10K 59/1216; H10K 59/65; H10K 2102/351

(57) ABSTRACT

An electronic device includes: a first electronic unit; a first transistor electrically connected to the first electronic unit and including a first polysilicon semiconductor; a first insulating layer disposed on the first polysilicon semiconductor; an oxide metal layer disposed on the first insulating layer; a second transistor electrically connected to the first electronic unit and the first transistor and including a first oxide semiconductor; and a second insulating layer disposed between the metal oxide layer and the first oxide semiconductor, wherein the oxide metal layer includes a first pattern overlapping with the first polysilicon semiconductor and a second pattern overlapping with the first oxide semiconductor, a thickness of the second insulating layer between the second pattern and the first oxide semiconductor is greater than or equal to 1000 Å and less than or equal to 8000 Å.

### CROSS-REFERENCE TO RELATED APPLICATIONS

This application claims the benefits of the Chinese Patent Application Ser. No. 202411106445.8, filed on Aug. 13, 2024, the subject matter of which is incorporated herein by reference.

### BACKGROUND

### Field

The present disclosure relates to an electronic device. More specifically, the present disclosure relates to an electronic device with an oxide transistor having high carrier mobility.

### Description of Related Art

Conventional electronic devices using oxide transistors often face the problem of insufficient carrier mobility, resulting in poor performance of the electronic devices. To improve this problem, some electronic devices use low-temperature polysilicon transistors to replace oxide transistors, but this causes leakage current problems.

Therefore, it is desirable to provide a novel electronic device to solve the aforesaid problems.

### SUMMARY

The present disclosure provides an electronic device, which comprises: a substrate, a first electronic unit, a first transistor, a first insulating layer, an oxide metal layer, a second transistor and a second insulating layer. Herein, the first electronic unit is disposed on the substrate. The first transistor is disposed on the substrate, electrically connected to the first electronic unit, and comprising a first polysilicon semiconductor. The first insulating layer is disposed on the first polysilicon semiconductor. The oxide metal layer is disposed on the first insulating layer. The second transistor is electrically connected to the first electronic unit and the first transistor, and comprising a first oxide semiconductor. The second insulating layer is disposed between the oxide metal layer and the first oxide semiconductor. Herein, the oxide metal layer comprises a first pattern and a second pattern separated from each other, the first pattern and the first polysilicon semiconductor are overlapped, the second pattern and the first oxide semiconductor are overlapped, a thickness of the second insulating layer between the second pattern and the first oxide semiconductor is greater than or equal to 1000 Å and less than or equal to 8000 Å.

Other novel features of the disclosure will become more apparent from the following detailed description when taken in conjunction with the accompanying drawings.

### BRIEF DESCRIPTION OF DRAWINGS

FIG. 1 is a schematic view of a basic driving circuit of an electronic device according to one embodiment of the present disclosure.

FIG. 2 is a top view of a part of an active region of an electronic device according to one embodiment of the present disclosure.

FIG. 3 is a cross-sectional schematic view of a part of an active region and a part of a peripheral region in an electronic device according to one embodiment of the present disclosure.

FIG. 4 is a cross-sectional schematic view of a part of an active region and a part of a peripheral region in an electronic device according to one embodiment of the present disclosure.

FIG. 5 is a cross-sectional schematic view of a part of an active region and a part of a peripheral region in an electronic device according to one embodiment of the present disclosure.

FIG. 6 is a cross-sectional schematic view of a part of an active region and a part of a peripheral region in an electronic device according to one embodiment of the present disclosure.

FIG. 7 is a cross-sectional schematic view of a part of an active region in an electronic device according to one embodiment of the present disclosure.

FIG. 8 is a cross-sectional schematic view of a part of an active region in an electronic device according to one embodiment of the present disclosure.

FIG. 9A to FIG. 9E are cross-sectional schematic views showing a manufacturing process of a part of an active region in an electronic device according to one embodiment of the present disclosure.

FIG. 10 is a top view of a part of an electronic device according to one embodiment of the present disclosure.

FIG. 11 is a cross-sectional schematic view of a part of a sensing region and a non-sensing region in an electronic device according to one embodiment of the present disclosure.

FIG. 12 is a schematic view of partial circuit arrangement of a drive circuit of an electronic unit and a sensing driving circuit in an electronic device according to one embodiment of the present disclosure.

FIG. 13A is a top view of a part of an electronic device according to one embodiment of the present disclosure.

FIG. 13B is a cross-sectional schematic view of a part of an electronic device according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

Reference will now be made in detail to exemplary embodiments of the present disclosure, examples of which are illustrated in the accompanying drawings. Whenever possible, the same reference numbers are used in the drawings and the description to refer to the same or like parts.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “substantially”, or “approximately”, are generally interpreted as within 10%, 5%, 3%, 2%, 19%, or 0.5% of a given value or range. The quantity given here is an approximate quantity, that is, without specifying “about”, “approximately”, “substantially” and “approximately”, “about”, “approximately”, “substantially” and “approximately” can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

It the present disclosure, the distance, the width, the length and the thickness may be measured by using an optical microscope (OM) or by using a cross-sectional image of a scanning electron microscope (SEM), but the present disclosure is not limited thereto. In addition, the same photograph may be used or more than one photograph may be used to measure the distance, the width, the length and the thickness. Furthermore, any two values or directions used for comparison may have a certain error. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

Furthermore, in the present disclosure, unless otherwise specified, the electrical connection between two elements may include a direct connection or an indirect connection. In an indirect connection, there may be one or more other elements, such as resistors, capacitors, or inductors, between the two elements. Electrical connections are used to transmit one or more signals, such as direct or alternating current or voltage, depending on the actual application.

The electronic device of the present disclosure may include, for example, a display device, a sensing device, an antenna device, a touch device, a tiled device, or other suitable electronic devices, but the present disclosure is not limited thereto. The display device of the present disclosure may be a non-self-luminous display device or a self-luminous display device, such as a liquid crystal display, a cholesteric liquid crystal display, an electro-phoretic display, an organic light emitting diode display or a light emitting diode display, but the present disclosure is not limited thereto. The display device may include a light emitting diode, a light conversion layer or other suitable materials, or a combination thereof, but the present disclosure is not limited thereto. The light emitting diode may include, for example, an organic light emitting diode (OLED), a mini LED, a micro LED or a quantum dot LED (which may include QLED or QDLED), but the present disclosure is not limited thereto. The light conversion layer may include wavelength conversion materials and/or light filtering materials, and the light conversion layer may comprise, for example, fluorescence, phosphors, quantum dots (QDs), other suitable materials or a combination thereof, but the present disclosure is not limited thereto. The sensing device may, for example, include a biosensor, a touch sensor, a fingerprint sensor, an infrared sensor, a temperature sensor, other suitable sensors, or a combination of the above types of sensors. The antenna device may be, for example, a liquid crystal antenna or other types of antennas, but the present disclosure is not limited thereto. The tiled device may be, for example, a tiled display device or a tiled antenna device, but the present disclosure is not limited thereto. The electronic device may comprise an electronic component, which may include passive components, active components, or a combination thereof, such as capacitors, resistors, inductors, varactor diodes, variable capacitors, filters, diodes, transistors, sensors, micro-electromechanical systems (MEMS), chips, etc., but the present disclosure is not limited thereto. It should be noted that the electronic device of the preset disclosure may be any combination of the above devices, but the present disclosure is not limited thereto.

In addition, the shape of the electronic device may be rectangular, circular, polygonal, a shape with curved edges, or other suitable shapes. The electronic device may have peripheral systems such as a drive system, a control system, a light source system, a shelf system, etc. to support a display device, an antenna device, or a tiled device.

It should be noted that the following embodiments may be implemented by replacing, reorganizing, or mixing features of several different embodiments without departing from the spirit of the present disclosure to implement other embodiments. The features of the various embodiments may be mixed and matched as desired as long as they do not violate the spirit of the invention or conflict with each other.

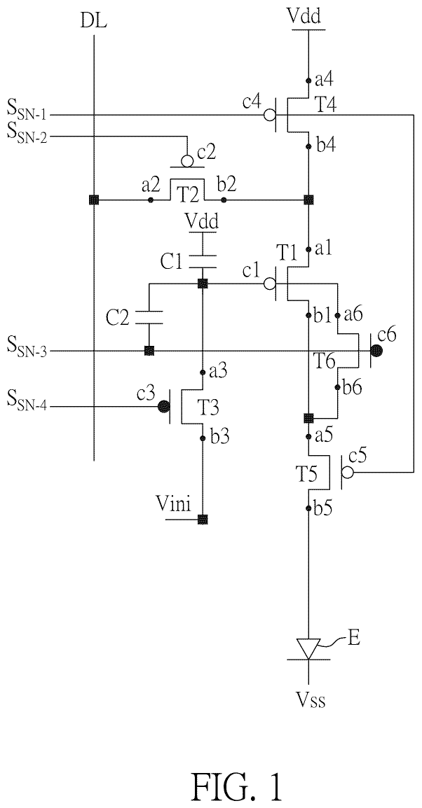

FIG. 1 is a schematic view of a basic driving circuit of an electronic device according to one embodiment of the present disclosure.

In one embodiment of the present disclosure, the basic driving circuit of the electronic device 1 may comprise a driver transistor T1, a writing transistor T2, a reset transistor T3, a transistor T4, a transistor T5 and a switch transistor T6, but the present disclosure is not limited thereto. At least one of the driver transistor T1, the writing transistor T2, the reset transistor T3, the transistor T4, the transistor T5 and the switch transistor T6 may be electrically connected to an electronic unit E. The driver transistor T1 may comprise a first end a1, a second end b1 and a control end c1, wherein the first end a1 may be a drain or a source, the second end b1 may be a drain or a source, and the control end c1 may be a gate. The writing transistor T2 may comprise a first end a2, a second end b2 and a control end c2, wherein the first end a2 may be a drain or a source, the second end b2 may be a drain or a source, and the control end c2 may be a gate. The reset transistor T3 may comprise a first end a3, a second end b3 and a control end c3, wherein the first end a3 may be a drain or a source, the second end b3 may be a drain or a source, and the control end c3 may be a gate. The transistor T4 may comprise a first end a4, a second end b4 and a control end c4, wherein the first end a4 may be a drain or a source, the second end b4 may be a drain or a source, and the control end c4 may be a gate. The transistor T5 may comprise a first end a5, a second end b5 and a control end c5, wherein the first end a5 may be a drain or a source, the second end b5 may be a drain or a source, and the control end c5 may be a gate. The switch transistor T6 may comprise a first end a6, a second end b6 and a control end c6, wherein the first end a6 may be a drain or a source, the second end b6 may be a drain or a source, and the control end c6 may be a gate.

In one embodiment, the semiconductor material in the driver transistor T1, the writing transistor T2, the transistor T4 and the transistor T5 may comprise, for example, low temperature polysilicon (LTPS), but the present disclosure is not limited thereto. In one embodiment, the semiconductor material in the reset transistor T3 and the switch transistor T6 may comprise a metal oxide, such as indium gallium zinc oxide (IGZO), indium zinc oxide (IZO), indium gallium oxide (IGO), or indium gallium zinc tin oxide (IGZTO), but the present disclosure is not limited thereto.

In one embodiment, the first end a1 of the driver transistor T1 may be electrically connected to the second end b2 of the writing transistor T2 and the second end b4 of the transistor T4, the second end b1 of the driver transistor T1 may be electrically connected to the first end a5 of the transistor T5, and the control end c1 of the driver transistor T1 may be electrically connected to the first end a6 of the switch transistor T6 and may be electrically connected to a capacitor C2. The first end a2 of the writing transistor T2 may be electrically connected to a data line DL, and the control end c2 of the writing transistor T2 may be electrically connected to a scan line S_{SN-2}. The first end a3 of the reset transistor T3 may be electrically connected to the control end c1 of the driver transistor T1 and form a capacitor C1 together with a high voltage Vdd, the second end b3 of the reset transistor T3 may be electrically connected to an initial voltage Vini, and the control end c3 of the reset transistor T3 may be electrically connected to a scan line S_{SN-4}. The first end a4 of the transistor T4 may be electrically connected to a high voltage Vdd, and the control end c4 of the transistor T4 may be electrically connected to a scan line S_{SN-1}. The second end b5 of the transistor T5 may be electrically connected to the electronic unit E, and the control end c5 of the transistor T5 may be electrically connected to the control end c4 of the transistor T4. The second end b6 of the switch transistor T6 may be electrically connected to the first end a5 of the transistor T5, and the control end c6 of the switch transistor T6 may be electrically connected to a scan line S_{SN-3}. In one embodiment, the high voltage Vdd may be used to adjust the electronic unit E. One end of the electronic unit E is electrically connected to the second end b5 of the transistor T5, and another end of the electronic unit E is electrically connected to a low voltage Vss.

Hereinafter, structures of parts of the transistors in the electronic device according to one embodiment of the present disclosure are described below.

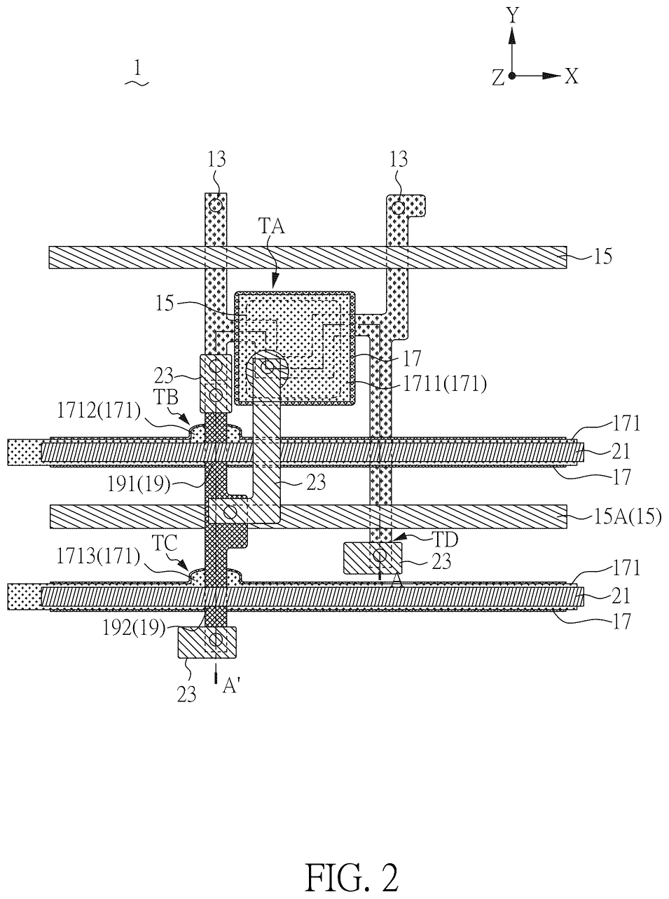

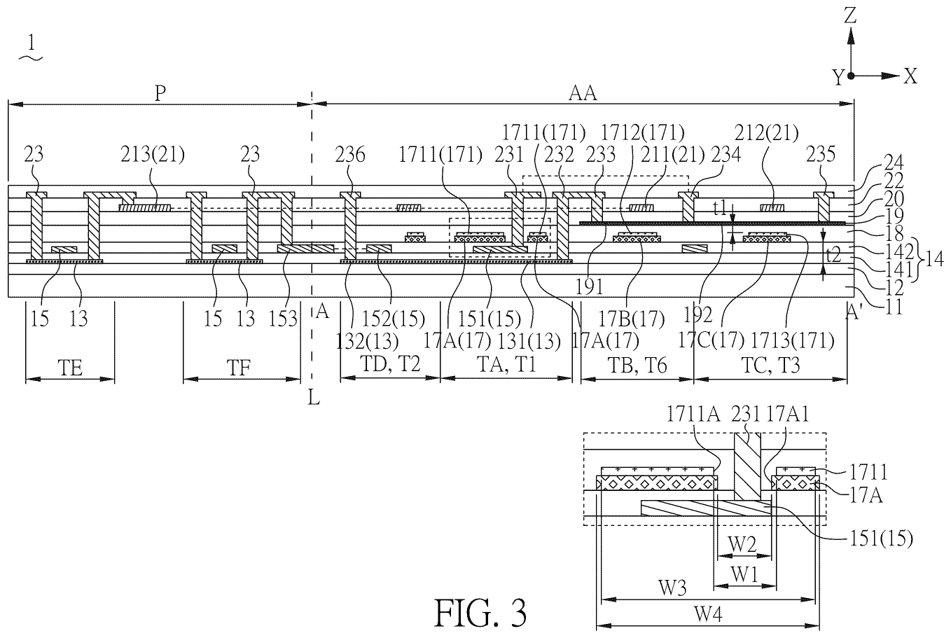

FIG. 2 is a top view of a part of an active region of an electronic device according to one embodiment of the present disclosure. FIG. 3 is a cross-sectional schematic view of a part of an active region and a part of a peripheral region in an electronic device according to one embodiment of the present disclosure. In FIG. 3, the cross-sectional schematic view of the part of the active region is a cross-sectional schematic view along the line A-A′ in FIG. 2. In addition, the dash line in FIG. 3 refers to that two components connected by the dash line are electrically connected to each other in other areas of the electronic unit.

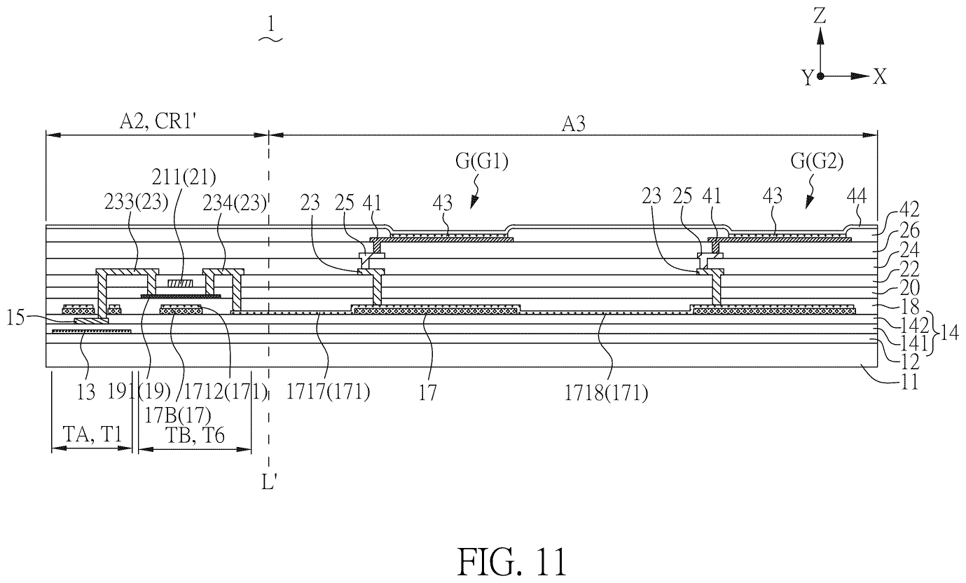

In one embodiment, as shown in FIG. 2 and FIG. 3, the electronic device 1 of the present disclosure comprises: a substrate 11; a first electronic unit (the electronic unit E shown in FIG. 1 or the green display unit G1 shown in FIG. 11) disposed on the substrate 11; a first transistor TA disposed on the substrate 11, wherein the first transistor TA is electrically connected to the first electronic unit (the electronic unit E shown in FIG. 1 or the green display unit G1 shown in FIG. 11) and comprises a first polysilicon semiconductor 131; a first insulating layer 14 disposed on the first polysilicon semiconductor 131; an oxide metal layer 171 disposed on the first insulating layer 14; a second transistor TB electrically connected to the first electronic unit E (the electronic unit E shown in FIG. 1 or the green display unit G1 shown in FIG. 11) and the first transistor TA and comprising a first oxide semiconductor 191; and a second insulating layer 18 disposed between the oxide metal layer 171 and the first oxide semiconductor 191; wherein the oxide metal layer 171 comprises a first pattern 1711 and a second pattern 1712 separated from each other, the first pattern 1711 and the first polysilicon semiconductor 131 are overlapped and the second pattern 1712 and the first oxide semiconductor 191 are overlapped.

More specifically, in the present disclosure, as shown in FIG. 2, in the top view direction Z, at least part of the first pattern 1711 of the oxide metal layer 171 and at least part of the first polysilicon semiconductor 131 are overlapped. In addition, as shown in FIG. 3, in a cross section, at least part of the first pattern 1711 of the oxide metal layer 171 and at least part of the first polysilicon semiconductor 131 are overlapped. Furthermore, as shown in FIG. 2, in a top view direction Z, at least part of the second pattern 1712 of the oxide metal layer 171 and at least part of the first oxide semiconductor 191 are overlapped. In addition, as shown in FIG. 3, in a cross section, at least part of the second pattern 1712 of the oxide metal layer 171 and at least part of the first oxide semiconductor 191 are overlapped.

In the present disclosure, by disposing the oxide metal layer 171, particularly by disposing the second pattern 1712 of the oxide metal layer 171 overlapped with the first oxide semiconductor 191, the carrier mobility of the second transistor TB comprising the first oxide semiconductor 191 can be improved, thereby improving the efficiency of the second transistor TB and the performance of the electronic device.

In the present disclosure, as shown in FIG. 2, the entire second metal layer 17 is disposed with the oxide metal layer 171. In other embodiments of the present disclosure, even not shown in the figure, not the entire second metal layer 17 is disposed with the oxide metal layer 171, and the oxide metal layer 171 is only disposed corresponding to the first oxide semiconductor 191. For example, in other embodiments of the present disclosure, even not shown in the figure, the oxide metal layer 171 of the electronic device 1 may not comprise the first pattern 1711, that is, the oxide metal layer 171 may be optionally not disposed on a portion 17A of the second metal layer 17 (as shown in FIG. 3).

In the present disclosure, as shown in FIG. 3, the electronic device 1 may comprise: a substrate 11; a buffer layer 12 disposed on the substrate 11; a polysilicon semiconductor layer 13 (including a first polysilicon semiconductor 131) disposed on the buffer layer 12; an insulating layer 141 disposed on the polysilicon semiconductor layer 13; a first metal layer 15 disposed on the insulating layer 141; an insulating layer 142 disposed on the first metal layer 15, wherein the insulating layer 141 and the insulating layer 142 form a first insulating layer 14; a second metal layer 17 disposed on the first insulating layer 14; an oxide metal layer 171 disposed on the second metal layer 17; a second insulating layer 18 disposed on the oxide metal layer 171; an oxide semiconductor layer 19 (including a first oxide semiconductor 191) disposed on the second insulating layer 18; a third insulating layer 20 disposed on the oxide semiconductor layer 19; a third metal layer 21 disposed on the third insulating layer 20; a fourth insulating layer 22 disposed on the third metal layer 21; a fourth metal layer 23 disposed on the fourth insulating layer 22; and a fifth insulating layer 24 disposed on the fourth metal layer 23. Herein, the fourth metal layer 23 is electrically connected to the first polysilicon semiconductor 131 and the first oxide semiconductor 191 respectively through a plurality of vias passing through the first insulating layer 14, the second insulating layer 18, the third insulating layer 20 and the fourth insulating layer 22.

In the present disclosure, the first transistor TA may comprise a part of the first polysilicon semiconductor 131, a portion 232 of the fourth metal layer 23 and a portion 151 of the first metal layer 15. Herein, the portion 151 of the first metal layer 15 may be used as a gate, and the portion 232 of the fourth metal layer 23 may be used as a source or a drain and electrically connected to the first polysilicon semiconductor 131. Even not shown in the figure, the fourth metal layer 23 may further comprise another portion used as a source and a drain and electrically connected to the first polysilicon semiconductor 131.

In the present disclosure, the second transistor TB may comprise a first oxide semiconductor 191, a portion 17B of the second metal layer 17, a portion 211 of the third metal layer 21 and portions 233, 234 of the fourth metal layer 23. Herein, the portion 17B of the second metal layer 17 and the portion 211 of the third metal layer 21 may be used as a bottom gate and a top gate respectively. One of the portions 233, 234 of the fourth metal layer 23 may be used as a source, the other may be used as a drain, and the portions 233, 234 of the fourth metal layer 23 may be electrically connected to the first oxide semiconductor 191 respectively.

In the present disclosure, the electronic device 1 may further comprise an oxide semiconductor layer 19 disposed on the substrate 11; and a third transistor TC electrically connected to the first transistor TA (as shown by the dash line) and comprising a second oxide semiconductor 192, wherein a portion of the oxide semiconductor layer 19 is the first oxide semiconductor 191, and another portion of the oxide semiconductor layer 19 is the second oxide semiconductor 192. The oxide metal layer 171 comprises a third pattern 1713 overlapped with the second oxide semiconductor 192 and separated from the second pattern 1712.

More specifically, in the present disclosure, as shown in FIG. 2, in a top view direction Z, at least part of the third pattern 1713 of the oxide metal layer 171 and at least part of the second oxide semiconductor 192 are overlapped. In addition, as shown in FIG. 3, in a cross section, at least part of the third pattern 1713 of the oxide metal layer 171 and at least part of the second oxide semiconductor 192 are overlapped.

In the present disclosure, the third transistor TC may comprise a second oxide semiconductor 192, a portion 17C of the second metal layer 17, a portion 212 of the third metal layer 21, and portions 234, 235 of the fourth metal layer 23. Herein, the portion 17C of the second metal layer 17 and the portion 212 of the third metal layer 21 may be used as a bottom gate and a top gate respectively. One of the portions 234, 235 of the fourth metal layer 23 may be used as a source and the other one may be used as a drain, and the portions 234, 235 of the fourth metal layer 23 are electrically connected to the second oxide semiconductor 192 respectively.

In the present disclosure, as shown in FIG. 3, in the second transistor TB and the third transistor TC of the electronic device 1, the oxide metal layer 171 respectively comprises a second pattern 1712 and a third pattern 1713. In other embodiments of the present disclosure, even not shown in the figure, in the second transistor TB of the electronic device 1, the oxide metal layer 171 may not comprise the second pattern 1712, that is, the portion 17B of the second metal layer 17 may be not disposed with the oxide metal layer 171. In other embodiments of the present disclosure, even not shown in the figure, in the third transistor TC of the electronic device 1, the oxide metal layer 171 may not comprise the third pattern 1713, that is, the portion 17C of the second metal layer 17 may not be disposed with the oxide metal layer 171.

In the present disclosure, as shown in the top view of FIG. 2, the electronic device 1 may further comprise a conductive line 15A disposed between the second pattern 1712 and the third pattern 1713.

In the present disclosure, the portion 17A of the second metal layer 17 and the portion 151 of the first metal layer 15 may be overlapped to form a capacitor.

In the present disclosure, as shown in FIG. 3, the electronic device 1 may further comprise: a polysilicon semiconductor layer 13 disposed on the substrate 11; and another transistor TD comprising a second polysilicon semiconductor 132, wherein a portion of the polysilicon semiconductor layer 13 is the first polysilicon semiconductor 131, and another portion of the polysilicon semiconductor layer 13 is the second polysilicon semiconductor 132. Herein, the transistor TD may comprise the second polysilicon semiconductor 132, a portion 152 of the first metal layer 15 and a portion 236 of the fourth metal layer 23. The portion 152 of the first metal layer 15 may be used as a gate, and the portion 236 of the fourth metal layer 23 may be used as a source or a drain electrically connected to the second polysilicon semiconductor 132. Even not shown in the figure, the fourth metal layer 23 may further comprise another portion used as a source or a drain electrically connected to the second polysilicon semiconductor 132.

In the present embodiment, the first transistor TA may be, for example, a driver transistor, such as the driver transistor T1 shown in FIG. 1. In the present embodiment, the second transistor TB may be, for example, a switch transistor, such as the switch transistor T6 shown in FIG. 1. In the present embodiment, the third transistor TC may be, for example, a reset transistor, such as the reset transistor T3 shown in FIG. 1. In the present embodiment, the transistor TD may be, for example, a writing transistor, such as the writing transistor T2 shown in FIG. 1. However, the present disclosure is not limited thereto.

In the present disclosure, the “oxide metal layer” refers to, for example, the oxide metal layer 171 of the present embodiment and the oxide metal layer described in the subsequent embodiments, which can provide oxygen atoms to the oxide semiconductor and improve the reliability of the oxide semiconductor, so that the threshold voltage (Vth) of the transistor including the oxide semiconductor can be positive-biased. The thickness of the oxide metal layer may be about 30% to about 50% of the thickness of the oxide semiconductor layer, which is a numerical range for fully supplying oxygen atoms to the oxide semiconductor layer. When the thickness of the oxide metal layer is less than about 30% of the thickness of the oxide semiconductor layer, the oxide metal layer may not be able to sufficiently supply oxygen atoms to the oxide semiconductor layer, and the threshold voltage of the oxide semiconductor layer may be negative-biased. In the case where the thickness of the oxide metal layer exceeds about 50% of the thickness of the oxide semiconductor layer, an excessive amount of oxygen atoms may be supplied, causing the threshold voltage of the transistor including the oxide semiconductor layer to be too high.

In the present disclosure, the “oxide semiconductor” refers to, for example, the oxide semiconductor layer 19, the first oxide semiconductor 191 and the second oxide semiconductor 192 of the present embodiment and the oxide semiconductor described in the subsequent embodiments, which may be high mobility oxide (HMO) with mobility greater than 15 cm²/V-sec, and for example, the mobility may be between 36 cm²/V-sec and 80 cm²/V-sec.

In the present disclosure, the oxide metal layer and the oxide semiconductor may respectively a metal oxide comprising indium (In), zinc (Zn), gallium (Ga), tin (Sn) or aluminum (Al). For example, the material of the oxide metal layer and the oxide semiconductor layer may respectively comprise indium gallium zinc oxide (IGZO), indium tin oxide (ITO), indium tin gallium oxide (ITGO), indium zinc oxide (IZO), zinc oxide (ZnO), indium tin gallium zinc oxide (ITGZO) or indium gallium oxide (IGO). In one embodiment of the present disclosure, the oxide metal layer and the oxide semiconductor may comprise the same basic materials. In one embodiment of the present disclosure, the oxide metal layer and the oxide semiconductor may comprise the same materials. However, the present disclosure is not limited thereto. In one embodiment of the present disclosure, the oxide semiconductor may comprise IGZO, but the present disclosure is not limited thereto. Furthermore, in one embodiment of the present disclosure, the oxide metal layer and the oxide semiconductor may include doped carriers respectively, such as N-type carriers or P-type carriers, if necessary.

In the present disclosure, as shown in FIG. 3, the thickness t1 of the second insulating layer 18 between the second pattern 1712 and the first oxide semiconductor 191 may be greater than or equal to 1000 Å and less than or equal to 8000 Å (1000 Å≤t1≤8000 Å), for example, greater than or equal to 1000 Å and less than or equal to 5000 Å (1000 Å≤t1≤5000 Å), or greater than or equal to 1000 Å and less than or equal to 4000 Å (1000 Å≤t1≤4000 Å). Herein, the second insulating layer 18 may include a single layer or a multi-layer structure, and the material thereof may include silicon nitride, silicon oxide, silicon oxynitride, silicon carbonitride, aluminum oxide or a combination thereof respectively, but the present disclosure is not limited thereto. In one embodiment, the second insulating layer 18 at least comprises one silicon oxide layer, and the thickness of the silicon oxide layer may be greater than or equal to 1000 Å and less than or equal to 4000 Å (1000 Å≤thickness≤4000 Å). In one embodiment, the second insulating layer 18 comprises not only a silicon oxide layer (the thickness thereof may be greater than or equal to 1000 Å and less than or equal to 4000 Å), but also other insulating layers, but the layer in contact with the first oxide semiconductor 191 has to be a silicon oxide layer. When the thickness t1 of the second insulating layer 18 or the silicon oxide layer of the second insulating layer 18 is within the aforementioned range, it is beneficial for the oxide metal layer 171 to provide oxygen atoms to the oxide semiconductor layer 19.

In the present disclosure, as shown in FIG. 3, the thickness t2 of the first insulating layer 14 may be greater than or equal to 1000 Å and less than or equal to 5000 Å (1000 Å≤t2≤5000 Å), for example, greater than or equal to 1000 Å and less than or equal to 2000 Å (1000 Å≤t2≤2000 Å) or greater than or equal to 3000 Å and less than or equal to 5000 Å (3000 Å≤t2≤5000 Å). Herein, the first insulating layer 14 may include a single layer or a multi-layer structure, and the material thereof may include silicon nitride, silicon oxide, silicon oxynitride, silicon carbonitride, aluminum oxide or a combination thereof, but the present disclosure is not limited thereto. In one embodiment, the first insulating layer 14 at least comprises one silicon nitride layer, and the thickness thereof may be greater than or equal to 1000 Å and less than or equal to 2000 Å (1000 Å≤thickness≤2000 Å). In one embodiment, as shown in FIG. 2, the first insulating layer 14 may comprise an insulating layer 141 and an insulating layer 142, wherein the insulating layer 141 may be a silicon oxide layer and the thickness thereof may be greater than or equal to 1000 Å and less than or equal to 2000 Å (1000 Å≤thickness≤2000 Å), and the insulating layer 142 may be a silicon nitride layer, and a thickness thereof may be greater than or equal to 1000 Å and less than or equal to 2000 Å (1000 Å≤thickness≤2000 Å).

In the present disclosure, as shown in FIG. 3, the electronic device 1 may further comprise a conductive structure (comprising a portion 231 of the fourth metal layer 23), wherein the first pattern 1711 comprises an opening 1711A, and the conductive structure (comprising the portion 231 of the fourth metal layer 23) is electrically connected between the first transistor TA (for example, the portion 151 of the first metal layer 15 (i.e. the gate)) and the second transistor TB (for example, the portion 234 of the fourth metal layer 23 (i.e. the source or the drain)) through the opening 1711A of the first pattern 1711. More specifically, the portion 231 of the fourth metal layer 23 and the portion 234 of the fourth metal layer 23 are electrically connected (as shown by the dash line), so the conductive structure (including the portion 231 of the fourth metal layer 23) is electrically connected between the gate of the first transistor TA (i.e. the portion 151 of the first metal layer 15) and the source or the drain of the second transistor TB (i.e. the portion 234 of the fourth metal layer 23) through the opening 1711A of the first pattern 1711.

In the present disclosure, as shown in FIG. 3, the electronic device 1 may further comprise a conductive pattern (that is, the portion 17A of the second metal layer 17) overlapped with the first pattern 1711 and comprising an opening 17A1, wherein the first transistor TA comprises a gate (that is, the portion 151 of the first metal layer 15), and the conductive pattern (that is, the portion 17A of the second metal layer 17) is disposed between the first pattern 1711 and the gate of the first transistor TA (that is, the portion 151 of the first metal layer 15), and the conductive structure (comprising the portion 231 of the fourth metal layer 23) is electrically connected to the first transistor TA through the opening 17A1 of the conductive pattern (that is, the portion 17A of the second metal layer 17).

In the present disclosure, as shown in the enlarged view of FIG. 3, the width W1 of the opening 1711A of the first pattern 1711 may be greater than the width W2 of the opening 17A1 of the conductive pattern (that is, the portion 17A of the second metal layer 17) (W1>W2). In other embodiments, even not shown in the figure, the width W1 of the opening 1711A of the first pattern 1711 may be approximately equal to the width W2 of the opening 17A1 of the conductive pattern (that is, the portion 17A of the second metal layer 17).

In the present disclosure, as shown in FIG. 3, in a cross section, the width of the second metal layer 17 is greater than the width of the oxide metal layer 171 formed thereon. Alternatively, as shown in FIG. 2, in a top view direction Z, a projection of the oxide metal layer 171 on the substrate 11 is less than a projection of the second metal layer 17 on the substrate 11, or a projection of the oxide metal layer 171 on the substrate 11 falls within a projection of the second metal layer 17 on the substrate 11.

In other embodiments of the present disclosure, even not shown in the figure, in a cross section, the width of the second metal layer 17 may be substantially equal to the width of the oxide metal layer 171 disposed thereon. Or, in a top view direction Z, a projection of the oxide metal layer 171 on the substrate 11 may be substantially equal to a projection of the second metal layer 17 on the substrate 11, or a projection of the oxide metal layer 171 on substrate 11 and a projection of the second metal layer 17 on the substrate 11 are overlapped.

In the present disclosure, as shown in the enlarged view of FIG. 3, the width W3 of the first pattern 1711 may be less than the width W4 of the conductive pattern (that is, the portion 17A of the second metal layer 17) (W3<W4). In other embodiments, even not shown in the figure, the width W3 of the first pattern 1711 may be approximately equal to the width W4 of the conductive pattern (that is, the portion 17A of the second metal layer 17).

In the present disclosure, the aforesaid widths W1, W2, W3, W4 respectively refer to the maximums width of the said components.

In the present disclosure, as shown in FIG. 3, the electronic device 1 may comprise: an active region AA; and a peripheral region P adjacent to the active region AA. Herein, the first transistor TA, the second transistor TB, the third transistor TC and the transistor TD mentioned above are disposed in the active region AA. In addition, the electronic device 1 may comprise: a fourth transistor TE and a fifth transistor TF disposed in the peripheral region P and used as gate driving circuits. The fourth transistor TE may be the signal output transistor of the first gate driving circuit, and the fifth transistor TF may be the signal output transistor of the second gate driving circuit.

In the present disclosure, the “active region” refers to the region of the electronic device where the main components operate or are manipulated by the user, for example, a light-emitting unit, or where electromagnetic waves are sent or received, but the present disclosure is not limited thereto. In the present disclosure, the “peripheral region” refers to the region of the electronic device outside the active region.

In the present disclosure, as shown in FIG. 3, the fourth transistor TE may comprise a portion of the polysilicon semiconductor layer 13, a portion of the first metal layer 15 and portions of the fourth metal layer 23. Herein, the portion of the first metal layer 15 may be used as a gate, the portions of the fourth metal layer 23 may be used as a source and a drain respectively, and the portion of the fourth metal layer 23 is electrically connected to the portion 211 of the third metal layer 21 (the top gate of the second transistor TB) through a portion 213 of the third metal layer 21, as shown by the dash line. Thus, the fourth transistor TE of the peripheral region P may be electrically connected to the second transistor TB of the active region AA to drive the second transistor TB.

In the present disclosure, as shown in FIG. 3, the fifth transistor TF may comprise a portion of the polysilicon semiconductor layer 13, a portion of the first metal layer 15 and portions of the fourth metal layer 23, wherein the portion of the first metal layer 15 may be used as a gate, the portions of the fourth metal layer 23 may be used as a source and a drain respectively, and the portion of the fourth metal layer 23 is electrically connected to the portion 152 of the first metal layer 15 (the gate of the transistor TD) through a portion 153 of the first metal layer 15, as shown by the dash line. Thus, the fifth transistor TF in the peripheral region P can be electrically connected to the transistor TD in the active region AA to drive the transistor TD.

In the present disclosure, the substrate 11 may be a flexible substrate or a rigid substrate, and the material of the substrate 11 may comprise glass, quartz, sapphire, ceramics, plastics, polycarbonate (PC), polyimide (PI), polypropylene (PP), polyethylene terephthalate (PET), polymethylmethacrylate (PMMA), other suitable materials or a combination thereof, but the present disclosure is not limited thereto.

In the present disclosure, the first metal layer 15, the second metal layer 17, the third metal layer 21 and the fourth metal layer 23 may respectively comprise a metal, a metal oxide, an alloy thereof or a combination thereof, such as, gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), or aluminum zinc oxide (AZO), but the present disclosure is not limited thereto.

In the present disclosure, the buffer layer 12, the third insulating layer 20, the fourth insulating layer 22 and the fifth insulating layer 24 may respectively comprise a single layer or a multi-layer structure, and the material thereof may respectively include silicon nitride, silicon oxide, silicon oxynitride, silicon carbonitride, aluminum oxide or a combination thereof, but the present disclosure is not limited thereto.

In the present disclosure, the material of the polysilicon semiconductor layer 13 (comprising the first polysilicon semiconductor 131 and the second polysilicon semiconductor 132) may comprise polysilicon, such as low-temperature polysilicon (LTPS).

In the present disclosure, the “electronic unit”, for example, the first electronic unit E shown in FIG. 1 and electronic units in the subsequent embodiments, may comprise chip, light emitting diode, variable capacitor, variable resistor, variable capacitance diode, other suitable electronic components or a combination thereof, but the present disclosure is not limited thereto.

In the present disclosure, the “pattern”, for example, the first pattern 1711 and the second pattern 1712 shown in FIG. 2 and FIG. 3 and patterns described in the subsequent embodiments, refers to an independent piece, which can be a block, a line or with other suitable shape, but the present disclosure is not limited thereto.

In the present disclosure, the “portion” refers to one region of an independent piece.

In the present disclosure, the “structure”, for example, the conductive structure (including the portion 231 of the fourth metal layer 23) shown in FIG. 3 and structures described in the subsequent embodiments, is constituted of a component of a specific layer and its part that penetrates multiple insulating layers.

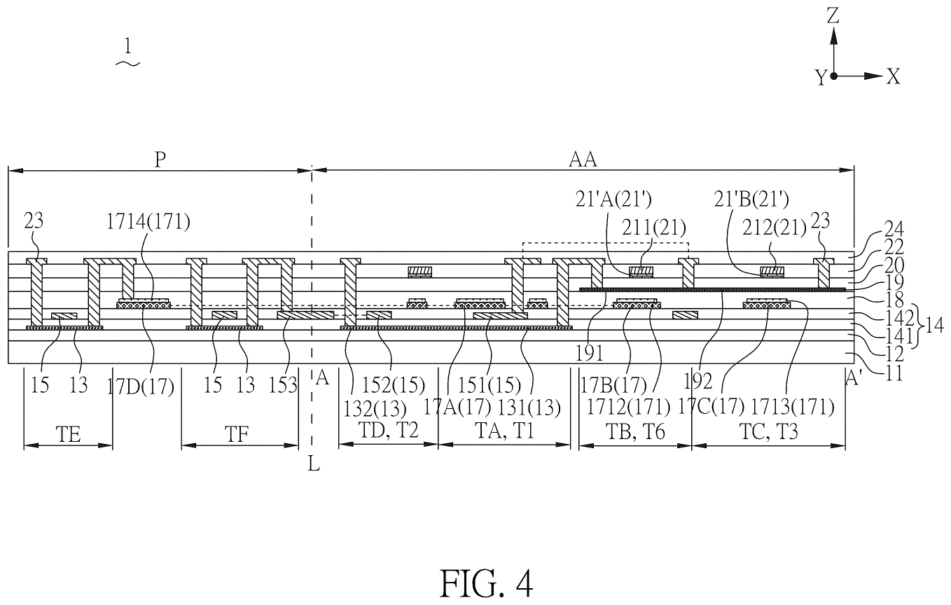

FIG. 4 is a cross-sectional schematic view of a part of an active region and a part of a peripheral region in an electronic device according to one embodiment of the present disclosure. In FIG. 4, the dash line indicates that the two components connected by the dash line are electrically connected to each other in other areas of the electronic component. The electronic device of FIG. 4 is similar to that of FIG. 3, except for the following differences.

In the present disclosure, as shown in FIG. 4, the electronic device 1 may further comprise another oxide metal layer 21′. Herein, the material and effect of the oxide metal layer 21′ are similar to those of the aforesaid oxide metal layer 171, and are not described again here.

In the present disclosure, as shown in FIG. 4, in the third transistor TC of the active region AA, the oxide metal layer 21′ may comprise a fourth pattern 21′B overlapped with the second oxide semiconductor 192, wherein the third pattern 1713 of the oxide metal layer 171 and the fourth pattern 21′B of the oxide metal layer 21′ are disposed on opposite sides of the second oxide semiconductor 192. In one embodiment, as shown in FIG. 4, in a cross section, at least part of the fourth pattern 21′B of the oxide metal layer 21′ and at least part of the second oxide semiconductor 192 are overlapped; and even not shown in the figure, in a top view direction Z, at least part of the fourth pattern 21′B of the oxide metal layer 21′ and at least part of the second oxide semiconductor 192 are overlapped. Herein, the fourth pattern 21′B of the oxide metal layer 21′ is disposed under the portion 212 of the third metal layer 21, and separated from the second oxide semiconductor 192 with a third insulating layer 20.

In the present disclosure, as shown in FIG. 4, in the second transistor TB of the active region AA, the oxide metal layer 21′ may comprise a fifth pattern 21′A overlapped with the first oxide semiconductor 191, wherein the fifth pattern 21′A of the oxide metal layer 21′ and the second pattern 1712 of the oxide metal layer 171 are disposed on two sides of the first oxide semiconductor 191. In one embodiment, as shown in FIG. 4, in a cross section, at least part of the fifth pattern 21′A of the oxide metal layer 21′ and at least part of the first oxide semiconductor 191 are overlapped; and even not shown in the figure, in a top view direction Z, at least part of the fifth pattern 21′A of the oxide metal layer 21′ and at least part of the first oxide semiconductor 191 are overlapped. Herein, the fifth pattern 21′A of the oxide metal layer 21′ is disposed under the portion 211 of the third metal layer 21 and separated from the first oxide semiconductor 191 with a third insulating layer 20.

In the present disclosure, as shown in FIG. 4, in the fourth transistor TE of the peripheral region P, the oxide metal layer 171 may further comprise a sixth pattern 1714 disposed on a portion 17D of the second metal layer 17, and the sixth pattern 1714 is electrically connected to the fourth transistor TE and the second transistor TB, as shown by the dash line. More specifically, a portion of the fourth metal layer 23 used as the source or the drain is electrically connected to the portion 17B of the second metal layer 17 (the bottom gate of the second transistor TB) through the portion 17D of the second metal layer 17 and the sixth pattern 1714 of the oxide metal layer 171, as shown by the dash line. Thus, the fourth transistor TE of the peripheral region P may be electrically connected to the second transistor TB of the active region AA to drive the second transistor TB. Even not shown in the figure, in other embodiments of the present disclosure, the portion 17D of the second metal layer 17 may be selectively not disposed with the sixth pattern 1714 of the oxide metal layer 171, and a source or drain portion of the fourth metal layer 23 is electrically connected to the portion 17B of the second metal layer 17 (the bottom gate of the second transistor TB) through the portion 17D of the second metal layer 17.

In FIG. 4, other components, the materials thereof or the positions thereof may be as those described above and are not described again here.

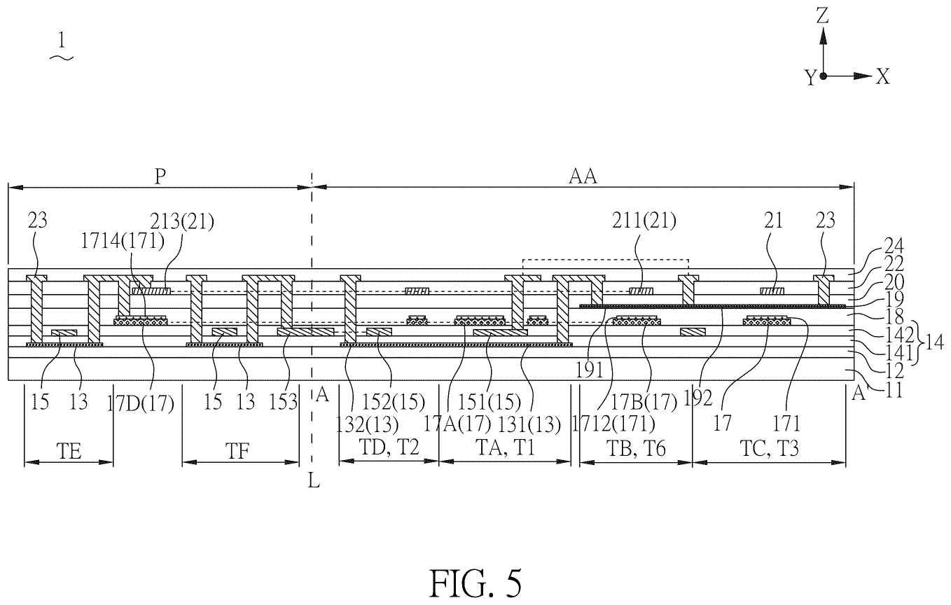

FIG. 5 is a cross-sectional schematic view of a part of an active region and a part of a peripheral region in an electronic device according to one embodiment of the present disclosure. In FIG. 5, the dash line indicates that the two components connected by the dash line are electrically connected to each other in other areas of the electronic component. The electronic device of FIG. 5 is similar to that of FIG. 3, except for the following differences.

In the present disclosure, as shown in FIG. 5, in the peripheral region P, the portion 17D of the second metal layer 17 may be disposed with the sixth pattern 1714 of the oxide metal layer 171. In the present disclosure, in the fourth transistor TE, a portion of the fourth metal layer 23 as the source or the drain may be electrically connected to the portion 17B of the second metal layer 17 (the bottom gate of the second transistor TB) through the portion 17D of the second metal layer 17 and the sixth pattern 1714 of the oxide metal layer 171, as indicated by the dash line. In addition, in the present disclosure, a portion of the fourth metal layer 23 as the source or the drain may be electrically connected to the portion 211 of the third metal layer 21 (the top gate of the second transistor TB) through the portion 213 of the third metal layer 21, as indicated by the dash line. Thus, the fourth transistor TE of the peripheral region P may be electrically connected to the second transistor TB of the active region AA to drive the second transistor TB.

In FIG. 5, other components, the materials thereof or the positions thereof may be as those described above and are not described again here.

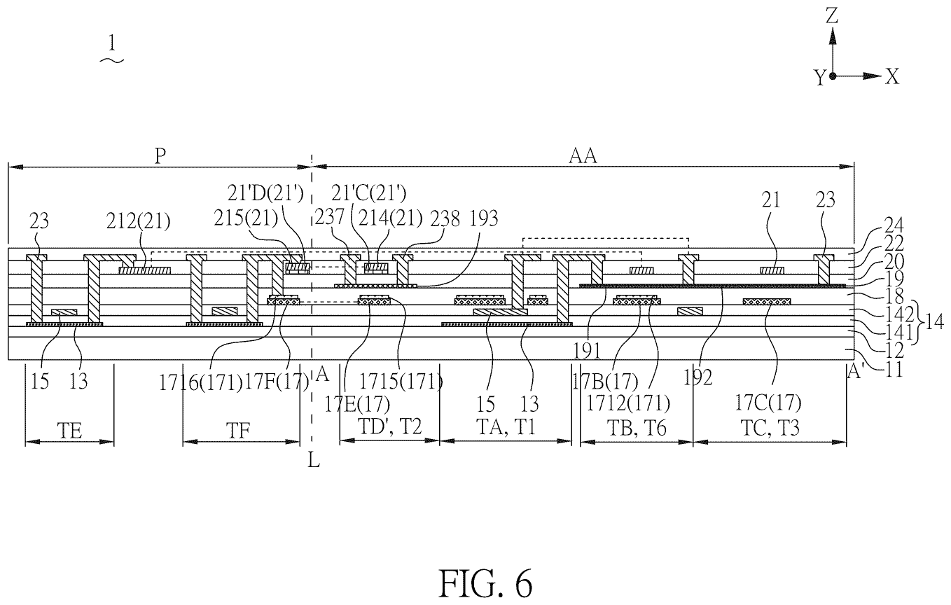

FIG. 6 is a cross-sectional schematic view of a part of an active region and a part of a peripheral region in an electronic device according to one embodiment of the present disclosure. In FIG. 6, the dash line indicates that the two components connected by the dash line are electrically connected to each other in other areas of the electronic component. The electronic device of FIG. 6 is similar to that of FIG. 3, except for the following differences.

In the present disclosure, as shown in FIG. 6, in the third transistor TC of the active region AA, the oxide metal layer 171 may not comprise the third pattern 1713 (as shown in FIG. 3), that is the portion 17C of the second metal layer 17 is not disposed with the oxide metal layer 171. In other embodiments of the present disclosure, even not shown in the figure, the portion 17C of the second metal layer 17 may be disposed with the oxide metal layer 171 as shown in FIG. 3.

In the electronic device shown in FIG. 3, the transistor TD in the active region AA is a transistor comprising the second polysilicon semiconductor 132. However, in the electronic device shown in FIG. 6, the transistor TD′ in the active region AA is a transistor comprising a third oxide semiconductor 193.

More specifically, as shown in FIG. 6, the transistor TD′ may comprise a third oxide semiconductor 193 of the oxide semiconductor layer 19, a portion 17E of the second metal layer 17, a portion 214 of the third metal layer 21, and portions 237, 238 of the fourth metal layer 23, wherein the portion 17E of the second metal layer 17 and the portion 214 of the third metal layer 21 are respectively used as a bottom gate and a top gate, one of the portions 237, 238 of the fourth metal layer 23 is used as a source and the other is used as a drain, and the portions 237, 238 of the fourth metal layer 23 are electrically connected to the third oxide semiconductor 193. In addition, the portion 17E of the second metal layer 17 is further disposed with a pattern 1715 of the oxide metal layer 171, a pattern 21′C of the oxide metal layer 21′ is further disposed under the portion 214 of the third metal layer 21, and the pattern 1715 of the oxide metal layer 171 and the pattern 21′C of the oxide metal layer 21′ are disposed on two sides of the third oxide semiconductor 193.

In other embodiments of the present disclosure, even not shown in the figure, a pattern 21′C of the oxide metal layer 21′ may be not disposed under the portion 214 of the third metal layer 21 of the transistor TD′.

In the present disclosure, as shown in FIG. 6, in the peripheral region P, in the fifth transistor TF, the fourth metal layer 23 as the source or the drain may be electrically connected to the portion 17E of the second metal layer 17 (the bottom gate of the transistor TD′) through the portion 17F of the second metal layer 17 and the pattern 1716 of the oxide metal layer 171, and the pattern 1716 of the oxide metal layer 171 is disposed on the portion 17F of the second metal layer 17. In addition, in the fifth transistor TF, the fourth metal layer 23 as the source and the drain may be electrically connected to the portion 214 of the third metal layer 21 (the top gate of the transistor TD′) through a portion 215 of the third metal layer 21, and a pattern 21′D of the oxide metal layer 21′ may be disposed under the portion 215 of the third metal layer 21.

In other embodiments of the present disclosure, even not shown in the figure, the portion 17F of the second metal layer 17 may be not disposed with the pattern 1716 of the oxide metal layer 171. In other embodiments of the present disclosure, even not shown in the figure, the pattern 21′D of the oxide metal layer 21′ may not be disposed under the portion 215 of the third metal layer 21.

In the present disclosure, since at least one side of the third oxide semiconductor 193 of the transistor TD′ is disposed with an oxide metal layer (for example, the pattern 1715 of the oxide metal layer 171 and/or the pattern 21′C of the oxide metal layer 21′), the performance of the transistor TD′ can be close to that of a polysilicon transistor (for example, the transistor TD shown in FIG. 3) even the transistor TD′ is an oxide semiconductor transistor, and the transistor TD′ can be used as, for example, the writing transistor T2 shown in FIG. 1.

In FIG. 6, other components, the materials thereof or the positions thereof may be as those described above and are not described again here.

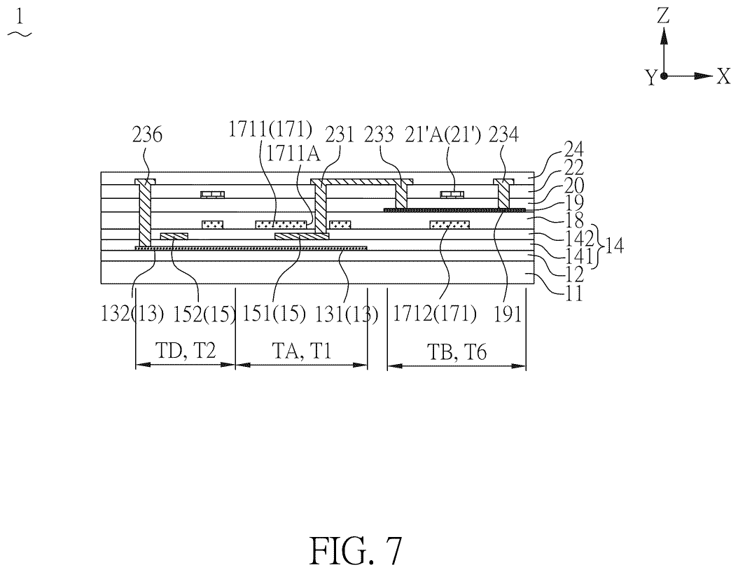

FIG. 7 is a cross-sectional schematic view of a part of an active region in an electronic device according to one embodiment of the present disclosure. FIG. 7 shows the first transistor TA, the second transistor TB and the transistor TD of the active region, and these transistors are similar to those shown in FIG. 4, except for the following differences.

In the present disclosure, as shown in FIG. 7, the electronic device 1 may not comprise the second metal layer 17 and the third metal layer 21 shown in FIG. 4.

In the present disclosure, as shown in FIG. 7, the second transistor TB may comprise the first oxide semiconductor 191 of the oxide semiconductor layer 19, the second pattern 1712 of the oxide metal layer 171, the fifth pattern 21′A of the oxide metal layer 21′ and the portions 233, 234 of the fourth metal layer 23. Herein, the second pattern 1712 of the oxide metal layer 171 and the fifth pattern 21′A of the oxide metal layer 21′ are used as the bottom gate and the top gate respectively, one of the portions 233, 234 of the fourth metal layer 23 is used as the source and the other is used as the drain, and the portions 233, 234 of the fourth metal layer 23 are electrically connected to the first oxide semiconductor 191 respectively.

In the present disclosure, as shown in FIG. 7, the conductive structure of the electronic device 1 (including the portion 231 of the fourth metal layer 23) is electrically connected to the portion 151 of the first metal layer 15 through the opening 1711A of the first pattern 1711. In addition, the first pattern 1711 and the portion 151 of the first metal layer 15 are overlapped to form a capacitor, wherein the first pattern 1711 can be used as one electrode of the capacitor.

In other embodiments of the present disclosure, even not shown in the figure, the third transistor TC shown in FIG. 3 to FIG. 6 may also comprise the structure of the second transistor TB shown in FIG. 7 and is not described here again.

In other embodiments of the present disclosure, even not shown in the figure, the electronic device 1 may comprise the portion 211 of the third metal layer 21 shown in FIG. 4, disposed on the fifth pattern 21′A of the oxide metal layer 21′. In other embodiments of the present disclosure, even not shown in the figure, the electronic device 1 may comprise the portion 211 of the third metal layer 21 shown in FIG. 4 to replace the fifth pattern 21′A of the oxide metal layer 21′ in FIG. 7.

In the present disclosure, when the oxide metal layer (for example, the oxide metal layer 171 and the oxide metal layer 21′) is used as an electrode, the doping elements and doping amounts thereof in the oxide metal layer material can be adjusted to enhance the conductivity of the oxide metal layer.

In FIG. 7, other components, the materials thereof or the positions thereof may be as those described above and are not described again here.

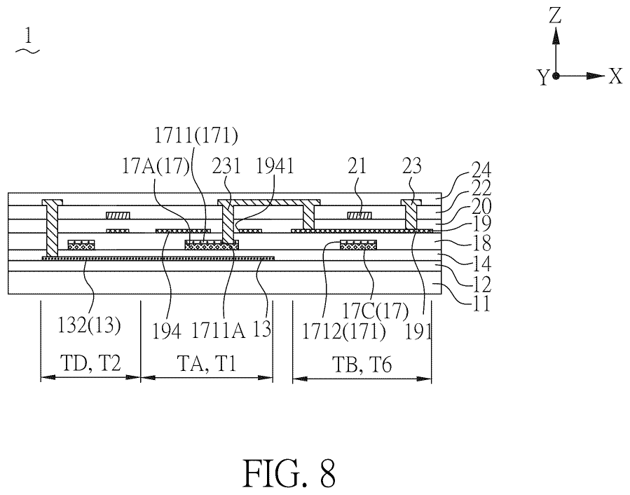

FIG. 8 is a cross-sectional schematic view of a part of an active region in an electronic device according to one embodiment of the present disclosure. FIG. 8 shows the first transistor TA, the second transistor TB and the transistor TD of the active region, and these transistors are similar to those shown in FIG. 3, except for the following differences.

In the present disclosure, as shown in FIG. 8, the electronic device 1 may not comprise the first metal layer 15 shown in FIG. 3.

In the present disclosure, as shown in FIG. 8, the oxide semiconductor layer 19 of the electronic device 1 further comprises a fourth oxide semiconductor 194, and the fourth oxide semiconductor 194 comprises an opening 1941. In the present disclosure, the conductive structure of the electronic device 1 (comprising the portion 231 of the fourth metal layer 23) may be electrically connected to the portion 17A of the second metal layer 17 through the opening 1941 of the fourth oxide semiconductor 194 and the opening 1711A of the first pattern 1711. In the present disclosure, the portion 17A of the second metal layer 17 and the fourth oxide semiconductor 194 are overlapped to form a capacitor, wherein the fourth oxide semiconductor 194 may be used as one electrode of the capacitor.

In other embodiments of the present disclosure, even not shown in the figure, the first pattern 1711 may not comprise the opening 1711A; thus, the conductive structure of the electronic device 1 (comprising the portion 231 of the fourth metal layer 23) may be electrically connected to the first pattern 1711 and the portion 17A of the second metal layer 17 through the opening 1941 of the fourth oxide semiconductor 194.

In other embodiments of the present disclosure, even not shown in the figure, the electronic device 1 may not comprise the second metal layer 17 shown in FIG. 8; at this time, in second transistor TB, the second pattern 1712 of the oxide metal layer 171 may be used as a bottom gate (as shown in FIG. 7). In addition, the first pattern 1711 may not comprise the opening 1711A, so the conductive structure of the electronic device 1 (comprising the portion 231 of the fourth metal layer 23) may be electrically connected to the first pattern 1711 through the opening 1941 of the fourth oxide semiconductor 194. Herein, the fourth oxide semiconductor 194 and the first pattern 1711 are overlapped to form a capacitor, and the fourth oxide semiconductor 194 and the first pattern 1711 are used as the upper electrode and the bottom electrode of the capacitor respectively.

In FIG. 8, other components, the materials thereof or the positions thereof may be as those described above and are not described again here.

Hereinafter, the method for manufacturing the electronic device of the present disclosure is briefly described below.

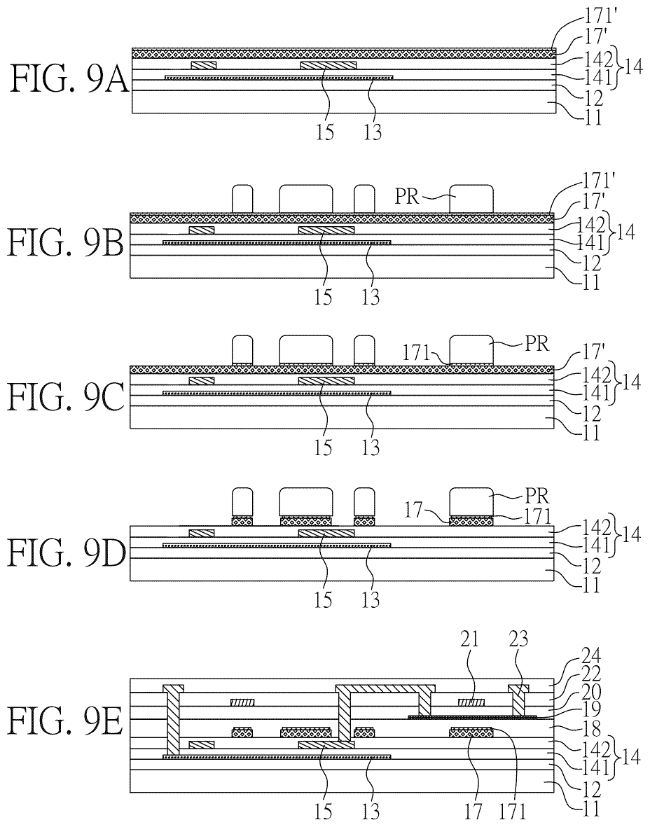

FIG. 9A to FIG. 9E are cross-sectional schematic views showing a manufacturing process of a part of an active region in an electronic device according to one embodiment of the present disclosure. Herein, the manufacture of the first transistor TA, the second transistor TB and the transistor TD in the active region of FIG. 3 is used as an example, and the methods for manufacturing other parts of the electronic device (for example, other parts of the active region or the peripheral region) or the electronic devices of other embodiments may be similar to that described below, and are not described again here.

As shown in FIG. 9A, a substrate 11 is provided first, and a buffer layer 12, a polysilicon semiconductor layer 13, an insulating layer 141, a first metal layer 15 and an insulating layer 142 are sequentially formed thereon. Next, a metal layer17′ is formed on the insulating layer 142, and a non-patterned oxide metal layer 171′ is formed on the metal layer17′. Then, a photoresist layer is formed on the non-patterned oxide metal layer 171′, and the photoresist layer is patterned through a lithography process to form a photoresist pattern PR on the non-patterned oxide metal layer 171′, as shown in FIG. 9B. The material of the photoresist layer can be selected as appropriate positive or negative photoresist according to the needs.

Next, a first etching process is performed to pattern the non-patterned oxide metal layer 171′ to form an oxide metal layer 171, as shown in FIG. 9C. Then, a second etching process is performed to pattern the metal layer17′ to form a second metal layer 17, as shown in FIG. 9D.

As shown in FIG. 9E, after forming the second metal layer 17, a second insulating layer 18, an oxide semiconductor layer 19, a third insulating layer 20, a third metal layer 21, a fourth insulating layer 22, a fourth metal layer 23 and a fifth insulating layer 24 are sequentially formed on the oxide metal layer 171 to obtain the electronic device of the present embodiment.

In the present embodiment, since the non-patterned oxide metal layer 171′ and the metal layer17′ are patterned through two etching processes, the oxide metal layer 171 is shrunk compared with the second metal layer 17. For example, in a top view direction, the area of the oxide metal layer 171 may be less than the area of the second metal layer 17, or the projection of the oxide metal layer 171 on the substrate 11 may completely fall within the projection of the second metal layer 17 on the substrate 11.

In other embodiments of the present disclosure, even not shown in the figure, the non-patterned oxide metal layer 171′ and the metal layer17′ may be patterned through one etching process. At least time, the oxide metal layer 171 does not shrink. For example, in the top view direction, the area of the oxide metal layer 171 may be approximately equal to the area of the second metal layer 17, or the projection of the oxide metal layer 171 on the substrate 11 may be approximately equal to the projection of the second metal layer 17 on the substrate 11 and completely fall within the projection of the second metal layer 17 on the substrate 11.

In FIG. 9A to FIG. 9E, other components, the materials thereof or the positions thereof may be as those described above and are not described again here.

Hereinafter, an electronic device incorporating a sensing unit will be described below.

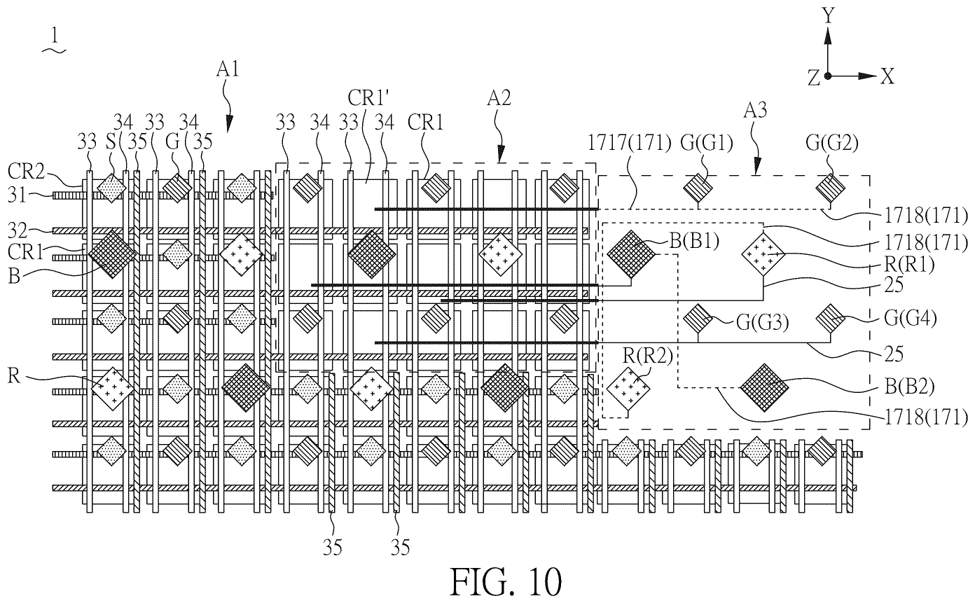

FIG. 10 is a top view of a part of an electronic device according to one embodiment of the present disclosure.

In one embodiment, as shown in FIG. 10, the electronic device 1 may comprise a first region A1, a second region A2 and a third region A3 disposed adjacent to each other. In addition, the electronic device 1 may comprise scan lines 31, 32, conductive lines 33, data lines 34 and read lines 35. Herein, the scan lines 31, 32 may extend along a first direction X, the conductive lines 33, the data lines 34 and the read lines 35 may extend along a second direction Y, and the first direction X and the second direction Y are different. In one embodiment, the first direction X may be approximately perpendicular to the second direction Y, but the present disclosure is not limited thereto. In one embodiment, the scan lines 31, 32 and the data lines 34 are used to provide transistor signals, the conductive lines 33 are used to provide a high voltage, and the read lines 35 are used to transmit signals sensed by a sensing unit.

In one embodiment, the first region A1 may be a main display region, and comprises a plurality of driving circuits CR1 respectively controlling electronic units and a plurality of sensing driving circuits CR2 respectively controlling sensing units; herein, the driving circuits CR1 of the electronic units may correspond to the electronic units (comprising the red display units R, the blue display units B and the green display units G), and the sensing driving circuit CR2 may correspond to the sensing units S. In one embodiment, the driving circuit CR1 of the electronic unit may be referred to the schematic view of the driving circuit shown in FIG. 1, but the present disclosure is not limited thereto. In one embodiment, the electronic units of the first region A1 may comprise the red display units R, the blue display units B, the green display units G and the sensing units S. In one embodiment, the scan lines 32 and the data lines 34 may be electrically connected to the driving circuits CR1 to provide signals to the driving circuits CR1 to respectively drive the red display units R, the blue display units B and the green display units G; the conductive lines 33 may be respectively connected to the driving circuits CR1 to respectively provide a high voltage to the red display units R, the blue display units B and the green display units G to adjust the brightness of the red display units R, the blue display units B and the green display units G; the scan lines 32 may be electrically connected to the sensing driving circuits CR2 to provide signals to the sensing driving circuits CR2 to drive the sensing units S, and the read lines 35 may be electrically connected to the sensing driving circuits CR2 to transmit the signals sensed by the sensing units S.

In one embodiment, the second region A2 may be a buffer display region. Herein, the second region A2 is similar to the first region A1, and the main difference is that the second region A2 comprises the electronic units (comprising the red display units R, the blue display units B and the green display units G) but does not comprise the sensing units S. Thus, in the second region A2, the scan lines 32, the read lines 35 and the sensing driving circuit CR2 are not disposed. Other region of the second region A2 (for example, the red display units R, the blue display units B, the green display units G and the circuit connection manners thereof) is similar to the first region A1, and is not described again here. In addition, the second region A2 may further be disposed with auxiliary driving circuits CR1′, which may be referred to the schematic view of the driving circuit shown in FIG. 1, but the present disclosure is not limited thereto. Herein, the scan lines 32 and the data lines 34 may be electrically connected to the auxiliary driving circuits CR1′ to provide signals to the auxiliary driving circuits CR1′, and the conductive lines 33 may be electrically connected to the auxiliary driving circuits CR1′ to provide a high voltage (Vdd). The function and connection manner of the auxiliary driving circuits CR1′ will be explained in detail later.

In one embodiment, the third region A3 may be a sensing region, and for example may be a camera region or a sensing unit disposing region, but the present disclosure is not limited thereto. In one embodiment, the electronic units in the third region A3 may comprise red display units R, blue display units B and green display units G, but the aforesaid driving circuits CR1, auxiliary driving circuits CR1′, sensing driving circuits CR2, scan lines 31, 32, conductive lines 33, data lines 34 and read lines 35 are not disposed in this region. The circuit connection and driving manners of the electronic units in the third region A3 will be described in detail later.

In one embodiment, the aforesaid red display units R, blue display units B and green display units G may be respectively a light emitting diode, for example, an organic light emitting diode (OLED), a mini LED, a micro LED or a quantum dot LED (which may comprise QLED or QDLED), but the present disclosure is not limited thereto. In one embodiment, the aforesaid sensing units S may be respectively a biometric sensor, a touch sensor, a fingerprint sensor, an infrared sensor, a temperature sensor, other suitable sensors or a combination of the above types of sensors. In one embodiment, the scan lines 31, 32, the conductive lines 33, the data lines 34 and the read lines 35 may respectively comprise a metal, a metal oxide, an alloy thereof or a combination thereof, and for example, may be gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), or aluminum zinc oxide (AZO), but the present disclosure is not limited thereto.

FIG. 11 is a cross-sectional schematic view of a part of a sensing region and a non-sensing region in an electronic device according to one embodiment of the present disclosure.

In one embodiment, as shown in FIG. 10 and FIG. 11, the electronic device 1 may comprise: a sensing region (for example, the third region A3); and a non-sensing region (for example, the second region A2) adjacent to the sensing region (for example, the third region A3), wherein the first electronic unit (for example, the green display unit G1) is disposed in the sensing region (for example, the third region A3), the second transistor TB is disposed in the non-sensing region (for example, the second region A2), and the oxide metal layer 171 comprises a seventh pattern 1717 electrically connected between the first electronic unit (for example, the green display unit G1) and the second transistor TB. In FIG. 11, the second region A2 of the electronic device 1 shows only a part of the driving circuit CR1′ shown in FIG. 10, the driving circuit CR1′ of the second region A2 of the electronic device 1 may be referred to, for example, those shown in FIG. 1 to FIG. 8 and is not described again here.

In one embodiment, the electronic device 1 may comprise: a fifth metal layer 25 disposed on the fifth insulating layer 24; a sixth insulating layer 26 disposed on the fifth metal layer 25; a first electrode layer 41 disposed on the sixth insulating layer 26; a pixel defining layer 42 disposed on the first electrode layer 41; a light emitting layer 43 disposed on the first electrode layer 41; and a second electrode layer 44 disposed on the light emitting layer 43.

In one embodiment, the material of the fifth metal layer 25 may comprise a metal, a metal oxide, an alloy thereof or a combination thereof, and for example, may be gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), or aluminum zinc oxide (AZO), but the present disclosure is not limited thereto. In one embodiment, the sixth insulating layer 26 may include a single layer or a multi-layer structure, and the material thereof may include silicon nitride, silicon oxide, silicon oxynitride, silicon carbonitride, aluminum oxide or a combination thereof respectively, but the present disclosure is not limited thereto. In one embodiment, the first electrode layer 41 may be a reflective electrode, and the material thereof may include aluminum, silver or a combination thereof, but the present disclosure is not limited thereto. In one embodiment, the material of the pixel defining layer 42 may comprise resin, polymer, photoresist or a combination thereof, but the present disclosure is not limited thereto. In one embodiment, the light emitting layer 43 may be an organic light emitting layer, but the present disclosure is not limited thereto. In one embodiment, the second electrode layer 44 may be a transparent electrode, and the material thereof may comprise ITO, IZO, ITZO or a combination thereof, but the present disclosure is not limited thereto.

As shown in FIG. 11, in one embodiment, in the non-sensing region (for example, the second region A2 shown in FIG. 10), the portion 234 of the fourth metal layer 23 of the second transistor TB is electrically connected to the seventh pattern 1717 of the oxide metal layer 171, and the first electrode layer 41 of the first electronic unit (for example, the green display unit G1) is electrically connected to the seventh pattern 1717 of the oxide metal layer 171 through a portion of the fifth metal layer 25 and a portion of the fourth metal layer 23, so the second transistor TB is electrically connected to the first electronic unit (for example, the green display unit G1) through the seventh pattern 1717 of the oxide metal layer 171.

In one embodiment, as shown in FIG. 10 and FIG. 11, the electronic device 1 may comprise: a sensing region (for example, the third region A3); a non-sensing region (for example, the second region A2) adjacent to the sensing region (for example, the third region A3); and a second electronic unit (for example, the green display unit G2). The first electronic unit (for example, the green display unit G1) and the second electronic unit (for example, the green display unit G2) are disposed in the sensing region (for example, the third region A3), the oxide metal layer 171 comprises an eighth pattern 1718 electrically connected between the first electronic unit (for example, the green display unit G1) and the second electronic unit (for example, the green display unit G2).

More specifically, as shown in FIG. 10 and FIG. 11, in one embodiment, the first electrode layer 41 of the first electronic unit (for example, the green display unit G1) is electrically connected to the eighth pattern 1718 of the oxide metal layer 171 through a portion of the fifth metal layer 25 and a portion of the fourth metal layer 23, and the first electrode layer 41 of the second electronic unit (for example, the green display unit G2) is electrically connected to the eighth pattern 1718 of the oxide metal layer 171 through a portion of the fifth metal layer 25 and a portion of the fourth metal layer 23, so the first electronic unit (for example, the green display unit G1) and the second electronic unit (for example, the green display unit G2) are electrically connected to each other.

In one embodiment, as shown in FIG. 10 and FIG. 11, the first electronic unit (for example, the green display unit G1) and the second electronic unit (for example, the green display unit G2) are electrically connected to the second transistor TB through the seventh pattern 1717 and the eighth pattern 1718 of the oxide metal layer 171. Thus, even the third region A3 is not disposed with a driving circuit, by the electrical connection of the oxide metal layer 171 and the auxiliary driving circuit CR1′ of the second region A2, the auxiliary driving circuit CR1′ of the second region A2 can drive the first electronic unit (for example, the green display unit G1) and the second electronic unit (for example, the green display unit G2) disposed in the third region A3.

In FIG. 11, a second metal layer 17 may be disposed below the seventh pattern 1717 and the eighth pattern 1718 of the oxide metal layer 171, wherein the patterns of the second metal layer 17 under the seventh pattern 1717 and the eighth pattern 1718 may respectively correspond to the light emitting layers 43 of the first electronic unit (for example, the green display unit G1) and the second electronic unit (for example, the green display unit G2) to serve as light shielding layers of the first electronic unit (for example, the green display unit G1) and the second electronic unit (for example, the green display unit G2). However, in other embodiments of the present disclosure, the second metal layer 17 may be optionally not disposed below the seventh pattern 1717 and the eighth pattern 1718 of the oxide metal layer 171.

However, in other embodiments of the present disclosure, the electronic unit disposed in the third region A3 may be not only electrically connected to the auxiliary driving circuit CR1′ of the second region A2 through the oxide metal layer, but also electrically connected to the auxiliary driving circuit CR1′ of the second region A2 through other metal layer or oxide metal layer.

In one embodiment, as shown in FIG. 10, the first electronic unit and the second electronic unit (for example, the green display units G3, G4) disposed in the third region A3 may be, for example, electrically connected to the portion 234 of the fourth metal layer 23 of the second transistor TB in the auxiliary driving circuit CR1′ directly through the fifth metal layer 25 shown in FIG. 11, and not electrically connected to the portion 234 of the fourth metal layer 23 through the oxide metal layer 171; but the present disclosure is not limited thereto.

In one embodiment, as shown in FIG. 10, the first electronic unit disposed in the third region A3 (for example, the blue display unit B1 or the red display unit R1) may be, for example, electrically connected to the portion 234 of the fourth metal layer 23 of the second transistor TB in the auxiliary driving circuit CR1′ though the fifth metal layer 25 shown in FIG. 11, and not electrically connected to the portion 234 of the fourth metal layer 23 through the oxide metal layer 171. The first electronic unit (for example, the blue display unit B1 or the red display electronic unit R1) and the second electronic unit (for example, the blue display unit B2 or the red display unit R2) disposed in the third region A3 may be electrically connected to each other through the eighth pattern 1718 of the oxide metal layer 171; but the present disclosure is not limited thereto.

In one embodiment, even not shown in the figure, the first electronic unit disposed in the third region A3 (for example, the blue display unit B1 or the red display unit R1) may be, for example, electrically connected to the portion 234 of the fourth metal layer 23 of the second transistor TB in the auxiliary driving circuit CR1′ through the seventh pattern 1717 of the oxide metal layer 171 shown in FIG. 11; the first electronic unit (for example, the blue display electronic unit B1 or the red display unit R1) and the second electronic unit (for example, the blue display unit B2 or the red display unit R2) disposed in the third region A3 may be electrically connected to each other through, for example, the fifth metal layer 25 shown in FIG. 11; but the present disclosure is not limited thereto.

In one embodiment, even not shown in the figure, the electronic units disposed in the third region A3 may be electrically connected to the auxiliary driving circuit CR1′ of the second region A3 shown in FIG. 10 through a metal layer (for example, the fifth metal layer 25 shown in FIG. 11) respectively; but the present disclosure is not limited thereto.

In one embodiment, even not shown in the figure, the electronic units disposed in the third region A3 may be electrically connected to the driving circuit (for example, the auxiliary driving circuit CR1′ of the second region A3 shown in FIG. 10) through, for example, the seventh pattern 1717 of the oxide metal layer 171 shown in FIG. 11 respectively; but the present disclosure is not limited thereto.

In one embodiment, even not shown in the figure, the electronic device 1 may comprise another auxiliary driving circuit disposed in the peripheral region to drive the electronic unit in the third region A3; but the present disclosure is not limited thereto.

In one embodiment, even not shown in the figure, a part of the auxiliary driving circuits CR1′ shown in FIG. 10 may drive one electronic unit, and another part of the auxiliary driving circuits CR1′ may drive two electronic units; but the present disclosure is not limited thereto.

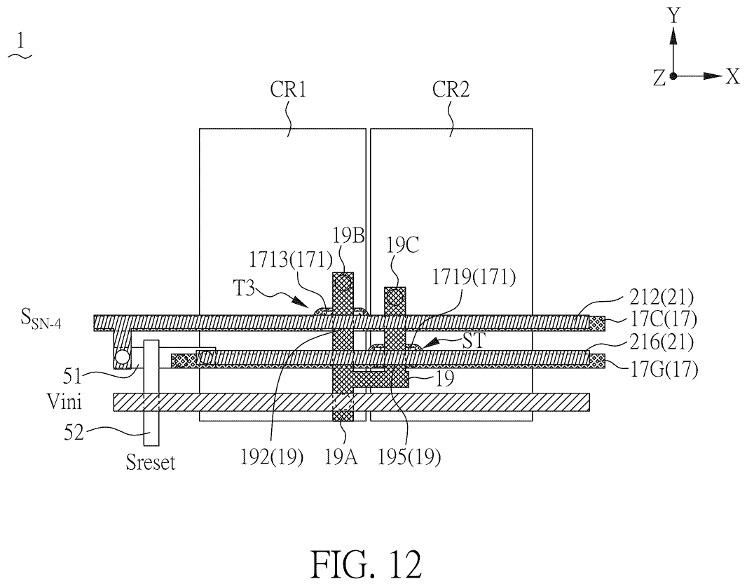

FIG. 12 is a schematic view of partial circuit arrangement of a drive circuit of an electronic unit and a sensing driving circuit in an electronic device according to one embodiment of the present disclosure. Please refer to FIG. 1 to FIG. 6 and FIG. 10 at the same time. To make the features clear, FIG. 11 only shows the wiring configuration of the reset transistor in the driving circuit of the electronic unit and the reset transistor of the sensing driving circuit. The wiring configuration of the other transistors can refer to the above content.

In one embodiment, as shown in FIG. 12, the oxide semiconductor layer 19 may comprise a second oxide semiconductor 192 and a fifth oxide semiconductor 195, and the second oxide semiconductor 192 and the fifth oxide semiconductor 195 are connected. In addition, the oxide metal layer 171 may comprise a third pattern 1713 and a pattern 1719, wherein the third pattern 1713 is disposed corresponding to the second oxide semiconductor 192, and the pattern 1719 is disposed corresponding to the fifth oxide semiconductor 195.

More specifically, as shown in FIG. 12, the reset transistor T3 disposed in the driving circuit CR1 of the electronic unit may comprise a portion 17C of the second metal layer 17, the third pattern 1713 of the oxide metal layer 171, the second oxide semiconductor 192 of the oxide semiconductor layer 19 and a portion 212 of the third metal layer 21, wherein the portion 17C of the second metal layer 17 and the portion 212 of the third metal layer 21 may be respectively used as a bottom gate and a top gate. Other structure of the reset transistor T3 may be referred to the third transistor TC shown in FIG. 2 to FIG. 6, and is not described again here. In addition, as shown in FIG. 12, the reset transistor ST disposed in the sensing driving circuit CR2 may comprise a portion 17G of the second metal layer 17, the pattern 1719 of the oxide metal layer 171, the fifth oxide semiconductor 195 of the oxide semiconductor layer 19 and a portion 216 of the third metal layer 21, wherein the portion 17G of the second metal layer 17 and the portion 216 of the third metal layer 21 may respectively be used as a bottom gate and a top gate.

In one embodiment, even not shown in the figure, the reset transistor T3 in the driving circuit CR1 of the electronic unit may not comprise the third pattern 1713 of the oxide metal layer 171 (as shown in FIG. 12). In one embodiment, even not shown in the figure, another oxide metal layer may be further included under the portion 212 of the third metal layer 21 of the reset transistor T3 in the driving circuit CR1 of the electronic device corresponding to the second oxide semiconductor 192 of the oxide semiconductor layer 19. In one embodiment, even not shown in the figure, another oxide metal layer may be further included under the portion 216 of the third metal layer 21 of the reset transistor ST in the sensing driving circuit CR2 corresponding to the pattern 1719 of the oxide metal layer 171.

In one embodiment, as shown in FIG. 12, the portion 17C of the second metal layer 17 and the portion 17G of the second metal layer 17 may be electrically connected in a bridge manner through the metal layer 51. Thus, the scan signal from the scan line S_{SN-4} can be input to the reset transistor T3 and the reset transistor ST at the same time.

In one embodiment, even not shown in the figure, the portion 17C of the second metal layer 17 and the portion 17G of the second metal layer 17 are not electrically connected to each other, and the reset transistor T3 in the driving circuit CR1 of the electronic unit and the reset transistor ST in the sensing driving circuit CR2 are controlled by different scan lines and different scan signals.

In one embodiment, as shown in FIG. 12, the portion 212 of the third metal layer 21 and the portion 216 of the third metal layer 21 can also be electrically connected in a bridge manner through a metal layer 52, so the reset control signal Sᵣₑₛₑₜ can also be input to the reset transistor T3 and the reset transistor ST.

In one embodiment, as shown in FIG. 12, the reset transistor T3 and the reset transistor ST can share the same end 19A, for example, they can share the source; and another end 19B (for example, the drain) of the reset transistor T3 and another end 19C (for example, the drain) of the reset transistor ST are respectively disposed in the driving circuit CR1 of the electronic unit and the sensing driving circuit CR2.

In one embodiment, even not shown in the figure, the driving circuit CR1 and the sensing driving circuit CR2 of the electronic unit may share the same oxide semiconductor. For example, as shown in FIG. 12, one of the second oxide semiconductor 192 or the fifth oxide semiconductor 195 of the oxide semiconductor layer 19 may be omitted.

For example, in one embodiment, only the second oxide semiconductor 192 of the oxide semiconductor layer 19 may be provided without providing the fifth oxide semiconductor 195 (as shown in FIG. 12), and the portion 17G of the second metal layer 17 (as shown in FIG. 12) and the portion 216 of the third metal layer 21 (as shown in FIG. 12) may not be provided. At this time, the end 19A as a common source may be disposed in the driving circuit CR1, in the sensing driving circuit CR2, or between the driving circuit CR1 and the sensing driving circuit CR2; the end 19B (for example, the drain) may be disposed in the driving circuit CR1 or between the driving circuit CR1 and the sensing driving circuit CR2; and the end 19C (for example, the drain) may be disposed in the sensing driving circuit CR2.

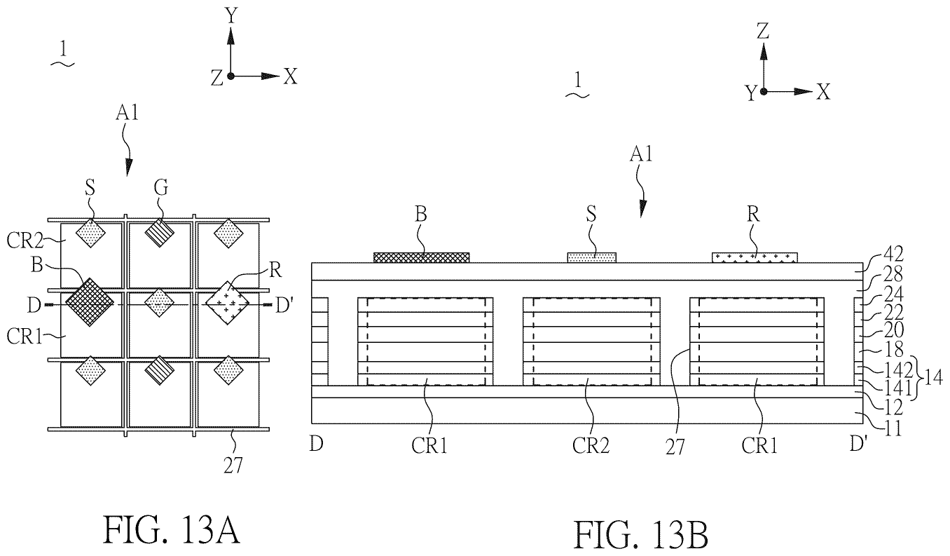

FIG. 13A is a top view of a part of an electronic device according to one embodiment of the present disclosure. FIG. 13B is a cross-sectional schematic view of a part of an electronic device according to one embodiment of the present disclosure. In FIG. 13B, the cross-sectional schematic view of a part of the electronic device is a cross-sectional schematic view along the line D-D′ of FIG. 13A. In addition, other elements of the electronic device 1 shown in FIG. 13A may refer to those of FIG. 10, and other elements of the electronic device 1 shown in FIG. 13B may refer to those of FIG. 3 to FIG. 8 and FIG. 11, which are not described again here.

In one embodiment, as shown in FIG. 13A and FIG. 13B, the first region A1 of the electronic device 1 as a main display area may further include a groove 27. More specifically, for example, the first insulating layer 14, the second insulating layer 18, the third insulating layer 20, the fourth insulating layer 22 and the fifth insulating layer 24 may be selectively patterned or removed to form the groove 27. In the present embodiment, the groove 27 penetrates through the first insulating layer 14, the second insulating layer 18, the third insulating layer 20, the fourth insulating layer 22 and the fifth insulating layer 24; but the present disclosure is not limited thereto. In other embodiments of the present disclosure, even not shown in the figure, the groove 27 may be disposed in at least one of the first insulating layer 14, the second insulating layer 18, the third insulating layer 20, the fourth insulating layer 22 and the fifth insulating layer 24.

In one embodiment, as shown in FIG. 13B, the groove 27 may be filled with a filling material 28, which may be photoresist, polymer material or a combination thereof, but the present disclosure is not limited thereto.

In one embodiment, as shown in FIG. 13A and FIG. 13B, the groove 27 is provided between the driving circuits CR1 of each electronic unit or between the driving circuit CR1 of the electronic unit and the sensing driving circuit CR2 in the first region A1 of the electronic device 1, but the present disclosure is not limited thereto. In other embodiments of the present disclosure, even not shown in the figure, the groove 27 may be selectively disposed between driving circuits CR1 of adjacent electronic units or between the driving circuit CR1 of the electronic unit and the sensing driving circuit CR2 adjacent thereto. In one embodiment, the groove 27 may be selectively not disposed between the driving circuit CR1 of the electronic unit and adjacent sensing driving circuit CR2. For example, a groove 27 is not disposed between the driving circuit CR1 corresponding to the blue display unit B and adjacent sensing driving circuit CR2, and a groove 27 is disposed between the driving circuit CR1 corresponding to the red display unit R and the adjacent sensing driving circuit CR2. When the driving circuit CR1 of the electronic unit and the adjacent sensing driving circuit CR2 are selectively not disposed with the groove 27, in one embodiment, the driving circuit CR1 of the electronic unit and the adjacent sensing driving circuit CR2 may include different oxide semiconductors (for example, the second oxide semiconductor 192 and the fifth oxide semiconductor 195 shown in FIG. 12). In another embodiment, the driving circuit CR1 of the electronic unit and the adjacent sensing driving circuit CR2 may optionally include a common oxide semiconductor (for example, the second oxide semiconductor 192 or the fifth oxide semiconductor 195 shown in FIG. 12), and the reset transistor T3 of the driving circuit CR1 and the reset transistor ST of the sensing driving circuit CR can share the end 19A (as shown in FIG. 12) as a common source.

In one embodiment, even not shown in the figure, the groove 27 may be disposed in the second region A2 of the electronic device 1 (as show in FIG. 10). More specifically, the groove 27 may be selectively disposed between the driving circuit CR1 and the auxiliary driving circuit CR1′ of the second region A2.

In one embodiment, even not shown in the figure, the groove 27 may be disposed in the third region A3 of the electronic device 1 (as shown in FIG. 10). More specifically, the region not disposed with the electronic unit (for example, the red display units R, the blue display units B and the green display units G) may be selectively disposed with the groove 27.

The above specific embodiments should be construed as merely illustrative and not limiting in any way the remainder of the present disclosure.

Although the present disclosure has been explained in relation to its embodiment, it is to be understood that many other possible modifications and variations can be made without departing from the spirit and scope of the disclosure as hereinafter claimed.

1. An electronic device, comprising:
a substrate;
a first electronic unit disposed on the substrate;
a first transistor disposed on the substrate, electrically connected to the first electronic unit, and comprising a first polysilicon semiconductor;
a first insulating layer disposed on the first polysilicon semiconductor;
an oxide metal layer disposed on the first insulating layer;
a second transistor electrically connected to the first electronic unit and the first transistor, and comprising a first oxide semiconductor; and
a second insulating layer disposed between the oxide metal layer and the first oxide semiconductor,
wherein the oxide metal layer comprises a first pattern and a second pattern separated from each other, the first pattern and the first polysilicon semiconductor are overlapped, the second pattern and the first oxide semiconductor are overlapped, and a thickness of the second insulating layer between the second pattern and the first oxide semiconductor is greater than or equal to 1000 Å and less than or equal to 8000 Å.

2. The electronic device of claim 1, further comprising: a conductive structure, wherein the first pattern has an opening, and the conductive structure is electrically connected between the first transistor and the second transistor through the opening of the first pattern.

3. The electronic device of claim 2, further comprising: a conductive pattern overlapped with the first pattern and having an opening, wherein the first transistor comprises a gate, the conductive pattern is disposed between the first pattern and the gate of the first transistor, and the conductive structure is electrically connected to the first transistor through the opening of the conductive pattern.

4. The electronic device of claim 3, wherein a width of the opening of the first pattern is greater than a width of the opening of the conductive pattern.

5. The electronic device of claim 3, wherein a width of the first pattern is less than a width of the conductive pattern.

6. The electronic device of claim 1, wherein a thickness of the first insulating layer is greater than or equal to 1000 Å and less than or equal to 5000 Å.

7. The electronic device of claim 1, further comprising:
an oxide semiconductor layer disposed on the substrate; and
a third transistor electrically connected to the first transistor and comprising a second oxide semiconductor,
wherein a portion of the oxide semiconductor layer is the first oxide semiconductor, another portion of the oxide semiconductor layer is the second oxide semiconductor, the oxide metal layer comprises a third pattern, and the third pattern is overlapped with the second oxide semiconductor and separated from the second pattern.

8. The electronic device of claim 7, further comprising: a conductive line, wherein the conductive line is disposed between the second pattern and the third pattern in a top view.

9. The electronic device of claim 7, further comprising: another oxide metal layer comprising a fourth pattern overlapped with the second oxide semiconductor, wherein the third pattern and the fourth pattern are disposed on opposite sides of the second oxide semiconductor.

10. The electronic device of claim 1, further comprising: another oxide metal layer comprising a fifth pattern overlapped with the first oxide semiconductor, wherein the fifth pattern and the second pattern are disposed on opposite sides of the first oxide semiconductor.

11. The electronic device of claim 1, wherein the electronic device comprises:
an active region;
a peripheral region adjacent to the active region; and
a fourth transistor disposed in the peripheral region,
wherein the second transistor is disposed in the active region, the oxide metal layer comprises a sixth pattern, and the sixth pattern is electrically connected to the fourth transistor and the second transistor.

12. The electronic device of claim 1, wherein the electronic device comprises:
a sensing region; and
a non-sensing region adjacent to the sensing region,
wherein the first electronic unit is disposed in the sensing region, the second transistor is disposed in the non-sensing region, the oxide metal layer comprises a seventh pattern, and the seventh pattern is electrically connected between the first electronic unit and the second transistor.

13. The electronic device of claim 1, wherein the electronic device comprises:
a sensing region;
a non-sensing region adjacent to the sensing region; and
a second electronic unit,
wherein the first electronic unit and the second electronic unit are disposed in the sensing region, the oxide metal layer comprises an eighth pattern, and the eighth pattern is electrically connected between the first electronic unit and the second electronic unit.

14. The electronic device of claim 1, wherein the second insulating layer comprise a silicon oxide layer.

15. The electronic device of claim 14, wherein a thickness of the silicon oxide layer is greater than or equal to 1000 Å and less than or equal to 4000 Å.

16. The electronic device of claim 14, wherein the silicon oxide layer contacts the first oxide semiconductor.

17. The electronic device of claim 1, wherein the first insulating layer comprises a silicon nitride layer.

18. The electronic device of claim 17, wherein a thickness of the silicon nitride layer is greater than or equal to 1000 Å and less than or equal to 2000 Å.

19. The electronic device of claim 17, wherein the first insulating layer further comprises a silicon oxide layer.

20. The electronic device of claim 19, wherein a thickness of the silicon oxide layer is greater than or equal to 1000 Å and less than or equal to 2000 Å.
